(19) United States
(12) Patent Application Publication
(10) Pub. No.: US 2005/0032340 A1
(43) Pub. Date: Feb. 10, 2005

(54) Semiconductor device and method of manufacturing the same

(75) Inventor: Teruo Takizawa, Matsumoto-City (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/885,717

(22) Filed: Jul. 8, 2004

(30) Foreign Application Priority Data
Jul. 24, 2003 (JP) 2003-279171

(51) Int. Cl. H01L 21/00; H01L 21/20; H01L 21/36

(52) U.S. Cl. 438/489; 438/479; 438/149; 438/164

(57) ABSTRACT

To provide a semiconductor device having a SOI structure including a less damaged strained silicon layer formed by a simple method and a method of manufacturing the same. A method of manufacturing a semiconductor device includes providing a substrate which has an insulating layer and a single-crystal silicon layer that has a prescribed pattern and is formed on the insulating layer, forming a strain promoting semiconductor layer whose lattice constant is different from that of the single-crystal silicon layer on the single-crystal silicon layer, forming a strained silicon layer by matching the single-crystal silicon layer to the strain promoting semiconductor layer, and removing the strain promoting semiconductor layer.

### BACKGROUND OF THE INVENTION

1. Field of Invention

The present invention relates to a semiconductor device and a method of manufacturing the same. More particularly, the invention relates to a semiconductor device including a semiconductor element having a strained silicon layer and a method of manufacturing such a semiconductor device.

2. Description of Related Art

Related art semiconductor devices including a substrate having a strained silicon layer have been developed to further miniaturization, speed up operation and to form fast and low power consumption semiconductor devices. The strained silicon layer is formed by, for example, forming a silicon germanium layer (SiGe layer), which is a mixed crystal of silicon and germanium, on a silicon substrate, and then forming a single-crystal silicon layer on the SiGe layer. Such a strained silicon layer has a changed band structure so that its degeneracy is lessened and electron scattering is restrained. Consequently, its electron mobility will increase.

A related art silicon-on-insulator (SOI) substrate which includes a buried oxide film in a silicon substrate has been developed to form fast and low power consumption semiconductor devices. A method of forming a SOI structure which includes the strained silicon layer has been developed so as to provide further miniaturized and faster semiconductor devices. See Japanese Unexamined Patent Laid-Open Publication No. 9-321307

### SUMMARY OF THE INVENTION

When the above-described SOI substrate including the strained silicon layer is formed, first, the SiGe mixed crystal layer is formed on a semiconductor layer of the SOI substrate. Second, the single-crystal silicon layer is formed on the SiGe mixed crystal layer, and then the strained silicon layer is obtained. In this manner, misfit transition or penetrating transition can occur in the SiGe mixed crystal layer by lattice matching between the semiconductor layer of the SOI substrate and the SiGe mixed crystal layer. When the strained silicon layer is formed on such a SiGe mixed crystal layer having a transition defect, the strained silicon layer takes over the defect from the SiGe mixed crystal layer and a fine field-effect transistors cannot be made. To prevent the defect from being taken over to the strained layer, a thick SiGe mixed crystal layer needs to be formed. However, it takes a long time to grow SiGe mixed crystal layer to be formed thick enough.

Also, to address or obtain advantages of the SOI substrate, such as lower parasitic capacitance, a thickness of a SOI layer of the SOI substrate should be less than a diffusion depth of a source-drain region of the field-effect transistor. When the strained silicon layer is formed on the above-described thick SiGe mixed crystal layer, the advantages of the SOI substrate cannot be received.

Further, to address or obtain the advantages of the SOI substrate, there is a technique of forming a buried insulating layer in the SiGe mixed crystal layer which has a thick and fine crystal condition. The buried insulating layer is formed by implanting an oxygen ion in high concentration into the SiGe mixed crystal layer, and then giving a heating treatment. According to this technique, the thickness of the SiGe mixed crystal layer can be lessened since the thick SiGe mixed crystal layer is separated by the buried insulating layer. Thus the advantages of the SOI substrate can be obtained. However, the SiGe mixed crystal layer can be damaged in the oxygen ion implanting process. As a result, a fine strained silicon layer cannot be formed.

An exemplary aspect of the present invention provides a semiconductor device having a SOI structure including a strained silicon layer formed by a simple method, and a method of manufacturing the same.

A method of manufacturing a semiconductor device of a first exemplary aspect of the present invention includes providing a substrate including an insulating layer and a single-crystal silicon layer that has a prescribed pattern and is formed on the insulating layer, forming a strain promoting semiconductor layer whose lattice constant is different from that of the single-crystal silicon layer on a prescribed region of the single-crystal silicon layer, forming a strained silicon layer by matching the single-crystal silicon layer to the strain promoting semiconductor layer and a removing the strain promoting semiconductor layer.

According to the above-described method of manufacturing a semiconductor device, the strain promoting semiconductor layer is only formed on the prescribed region of the single-crystal silicon layer. Therefore, the strained silicon layer is only formed in a limited area. This means that the fine strained silicon layer can be formed without forming the thick silicon germanium mixed crystal layer or forming the buried insulating layer to separate the thick SiGe mixed crystal layer in order to obtain the advantages of the SOI substrate. Consequently, the semiconductor device having an enhanced quality can be manufactured.

A method of manufacturing a semiconductor device of second exemplary aspect of the present invention includes providing a substrate including an insulating layer and a single-crystal silicon layer that has a prescribed pattern and is formed on the insulating layer, forming a strain promoting semiconductor layer whose lattice constant is different from that of the single-crystal silicon layer on the single-crystal silicon layer, forming a strained silicon layer by matching the single-crystal silicon layer to the strain promoting semiconductor layer and removing the strain promoting semiconductor layer.

According to the above-described method of manufacturing a semiconductor device, the substrate including the strained silicon layer is manufactured by forming the strain promoting semiconductor layer on the single-crystal silicon layer and then promoting a lattice relaxation. This means that the fine strained silicon layer can be formed without forming the thick silicon germanium mixed crystal layer or forming the buried insulating layer to separate the thick SiGe mixed crystal layer in order to obtain the advantages of the SOI substrate.

Further, since the single-crystal silicon layer having the prescribed pattern is formed in the SOI substrate, a more uniformly strained silicon layer is formed compared to a case where the strained layer is formed on an entire surface of the substrate. Also, the single-crystal silicon layer having the prescribed pattern can be useful when the strained silicon layer is formed only where a high performance semiconductor element is going to be formed, in a semiconductor device having a plurality of semiconductor elements.

In the method of manufacturing a semiconductor device of an exemplary aspect of the present invention, at least one of the following features may be included.

The strained silicon layer may be formed by giving a heat treatment.

The single-crystal silicon layer may have a smaller thickness than a thickness in which a defect-free single-crystal silicon layer is formed when formed on the strain promoting semiconductor layer.

A layer that contains germanium may be formed as the strain promoting semiconductor layer.

The strain promoting semiconductor layer may be removed by a wet etching using a boiling nitric acid.

The strain promoting semiconductor layer may be formed by any one of a metal organic chemical vapor deposition method, a molecular beam epitaxy method and ultra high vacuum chemical vapor deposition method.

The heat treatment may be carried out through a warm-up process, a fixed temperature process and a cool down process.

A semiconductor device of a third exemplary aspect of the present invention includes a field-effect transistor having the strained silicon layer obtained by the above-described methods as an active region.

### BRIEF DESCRIPTION OF THE DRAWINGS

FIG. 1 is a schematic of a semiconductor device formed by a method according to a first embodiment of the present invention;

FIG. 2 is a schematic of a semiconductor device formed by a method according to a second embodiment of the present invention;

FIG. 3 is a schematic showing a step to manufacture a semiconductor device according to the first exemplary embodiment of the present invention;

FIG. 4 is a schematic showing a step to manufacture a semiconductor device according to the first exemplary embodiment of the present invention;

FIG. 5A is a schematic showing a step to manufacture a semiconductor device according to the first exemplary embodiment of the present invention;

FIG. 5B is a schematic showing a step to manufacture a semiconductor device according to the first exemplary embodiment of the present invention;

FIG. 6 is a schematic showing a step to manufacture a semiconductor device according to the first exemplary embodiment of the present invention;

FIG. 7 is a schematic showing a step to manufacture a semiconductor device according to the second exemplary embodiment of the present invention;

FIG. 8 is a schematic showing a step to manufacture a semiconductor device according to the second exemplary embodiment of the present invention; and

FIG. 9 is a schematic showing a step to manufacture a semiconductor device according to the second exemplary embodiment of the present invention.

### DETAILED DESCRIPTION OF EXEMPLARY EMBODIMENTS

1. Semiconductor Device

1.1 First Exemplary Embodiment

A semiconductor device obtained by a method according to a first exemplary embodiment of the present invention is described below with reference to FIG. 1.

As shown in FIG. 1, the semiconductor device according to the first exemplary embodiment of the present invention has a silicon-on-insulator (SOI) structure. A metal-oxide-semiconductor (MOS) transistor 20 is formed on a SOI substrate 100. The SOI substrate 100 is formed by forming an insulating layer (an oxide silicon layer) 12 on a support substrate 10 and forming a strained silicon layer 14 having a prescribed pattern on the insulating layer 12. Since the strained silicon layer 14 has the prescribed pattern, the strained silicon layer 14 can substantially serves as isolation. The strained silicon layer 14 is a layer in which a lattice relaxation has taken place and whose thickness is from 1 nm to 10 nm.

A gate insulating layer 22 and a gate electrode 24 are formed on the strained silicon layer 14. A sidewall insulating layer 26 is formed on the sides of the gate insulating layer 22 and the gate electrode 24. A source-drain region 28, which is formed of an impurity layer, is formed in a part of the strained silicon layer 14, which is by the side of the sidewall insulating layer 26. An extension region 30 is formed in a part of the strained silicon layer 14 placed under the sidewall insulating layer 26.

1.2 Second Exemplary Embodiment

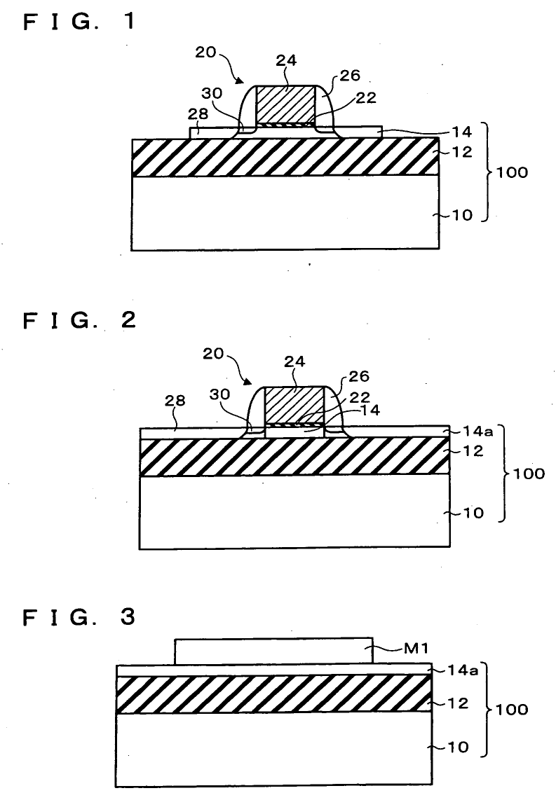

A semiconductor device according to a second exemplary embodiment of the present invention is described with reference to FIG. 2.

The semiconductor device according to the second exemplary embodiment is an example of the strained silicon layer 14 having a different pattern from that of the first exemplary embodiment. The same structures as those of the first exemplary embodiment are given identical reference numerals and those detailed explanations are omitted.

The semiconductor device according to the second exemplary embodiment of the present invention has the SOI structure. The MOS transistor 20 is formed on the SOI substrate 100, as shown in FIG. 2. The SOI substrate 100 is formed by forming the insulating layer (an oxide silicon layer) 12 on the support substrate 10, and forming a single-crystal silicon layer 14a and the strained silicon layer 14 to be mingled together in one plain.

The gate insulating layer 22 and the gate electrode 24 of the MOS transistor 20 are formed on the strained silicon layer 14. The strained silicon layer 14 is only provided where an active region (a channel region) of the MOS transistor 20 is formed. The sidewall insulating layer 26 is formed on the sides of the gate insulating layer 22 and the gate electrode 24. The source-drain region 28, which is formed of the impurity layer, is formed in the part of the strained silicon layer 14, which is located by the side of the sidewall insulating layer 26. In the part of the single-crystal silicon layer 14a placed under the sidewall insulating layer 26, the extension region 30 is formed.

2. Method of Manufacturing Semiconductor Device

2.1 First Exemplary Embodiment

A method of manufacturing a semiconductor device according to the first exemplary embodiment of the present invention is described with reference to FIGS. 3 through 6.
(1) First, as shown in FIG. 3, the SOI substrate 100, which has the insulating layer 12 and the semiconductor layer formed on the support substrate 10, is provided. In this exemplary embodiment, the single-crystal silicon layer 14a is employed as the semiconductor layer. The single-crystal silicon layer 14a has a thickness where a strain promoting semiconductor layer 16 can be formed without a defect on the single-crystal silicon layer 14a in a process described later. For example, when a silicon germanium mixed crystal layer is employed as the strain promoting semiconductor layer 16, the thickness of the single-crystal silicon layer 14a can be from 1 nm to 10 nm. In a case that the thickness of the single-crystal silicon layer 14a is less than 1 nm, it will be difficult to form a semiconductor element having the later formed strained silicon layer as a channel semiconductor layer. In a case that the thickness of the single-crystal silicon layer 14a is more than 10 nm, the single-crystal silicon layer 14a cannot be flawlessly matched with the strain promoting semiconductor layer 16 in a later process.

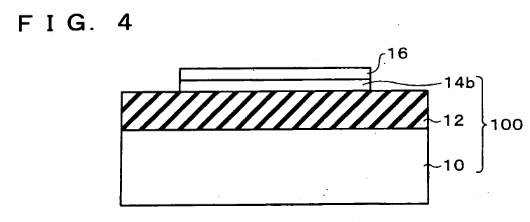

A mask layer M1 having a prescribed pattern, for example, which is a nitride film, is formed on the single-crystal silicon layer 14a. The mask layer M1 is formed to cover a region where the semiconductor element (MOS transistor 20) is going to be formed. Then, using the mask layer M1 as a mask, the single-crystal silicon layer 14a is etched and the single-crystal silicon layer 14b having the prescribed pattern is obtained. Since the single-crystal silicon layer 14b remains only where the MOS transistor 20 is formed, the single-crystal silicon layer 14b can serve as isolation.
(2) Second, as shown in FIG. 4, the strain promoting semiconductor layer 16 is formed on the single-crystal silicon layer 14b by an epitaxial growth method. A semiconductor layer having a different lattice constant from that of the single-crystal silicon layer 14b can be used as the strain promoting semiconductor layer 16, such as, a germanium layer, a silicon germanium layer, a film stack which includes the germanium layer and the silicon germanium layer and the like.

The strain promoting semiconductor layer 16 is formed by the epitaxial growth method, such as, metal organic chemical vapor deposition (MO-CVD), molecular beam epitaxy (MBE), ultra high vacuum chemical vapor deposition (UHV-CVD), liquid phase epitaxy (LPE) and the like.

As a silicon-based material, SiH₄, Si₂H₆, Si₂H₄Cl₂ and the like, and as a germanium-based material, GeH₄, Ge₂H₈ and the like are suitable for forming the layers described above.

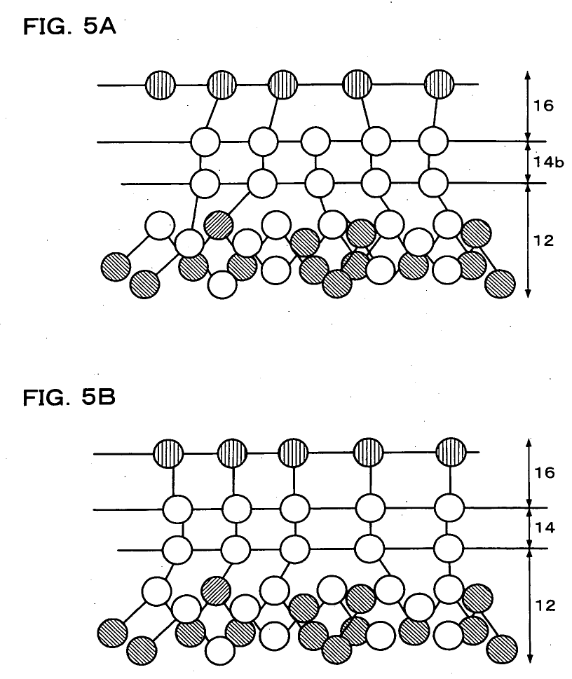

Then, a heating treatment is given to promote a lattice relaxation in the single-crystal silicon layer 14b, and then the strained silicon layer 14 is obtained. A condition of the lattice relaxation in the single-crystal silicon layer 14b is described with reference to FIG. 5A and FIG. 5B. Since a lattice constant of the germanium in the strain promoting semiconductor layer 16 (5.64 Å) is different from a lattice constant of the single-crystal silicon layer 14b (5.43 Å), a lattice mismatch between those layers happens after forming the strain promoting semiconductor layer 16 on the single-crystal silicon layer 14b. Thus, a stress is generated in each of the layers as shown in FIG. 5A. A heat treatment is carried out thereafter. Then a Si—Si bond or a Si—O bond at the boundary between the single-crystal silicon layer 14b and the insulating layer 12 is broken as if the bond slides and is cut off. Consequently, the strained silicon layer 14, which is matched to the strain promoting semiconductor layer 16, is formed as shown in the FIG. 5B. A temperature of the heat treatment is more than 100° C. A treating time of the heat treatment is changeable according to a thickness of the single-crystal silicon layer 14b, as long as the time is long enough that the lattice matching is taking place in the single-crystal silicon layer 14b, and long enough for the single-crystal silicon layer 14b to be turned into the strained silicon layer 14. Also, the heat treatment includes a warm-up process, a fixed temperature process and a cool down process. This series of processes may be carried out more than once.

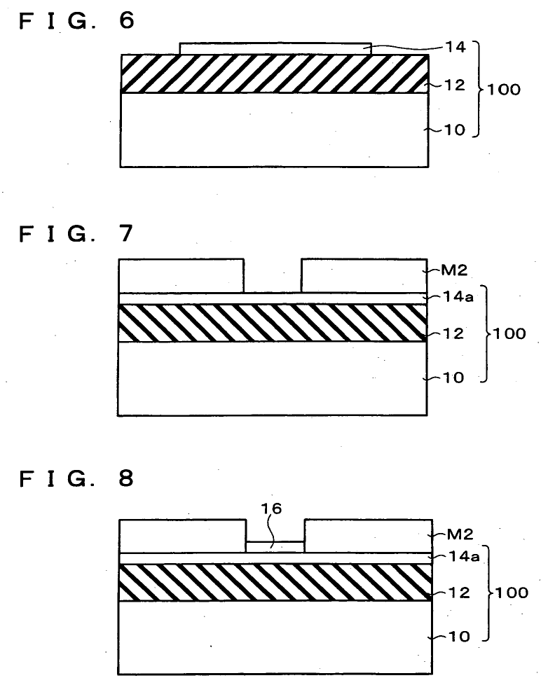

It is desirable to form a protective film (not shown in the figures) at least to cover an exposed end section of the single-crystal silicon layer 14b before the heat treatment. An insulating film, such as an oxide silicon film, may be employed as the protective film and formed by a chemical vapor deposition (CVD) method, for example. The protective film can reduce or prevent the end section of the single-crystal silicon layer 14b from being oxidized in a later heat treatment process.
(3) Third, the strain promoting semiconductor layer 16 is removed as shown in FIG. 6. The removal of the strain promoting semiconductor layer 16 can be carried out by commonly used etching techniques, such as wet etching and dry etching. Particularly, it is desirable to remove the strain promoting semiconductor layer 16 by a wet etching which uses a boiling nitric acid. In this case, there is an advantage that the strained silicon layer 14 will be less damaged compared to a case which the strain promoting semiconductor layer 16 is removed by dry etching. In the above-mentioned manner, the SOI substrate 100 including the strained silicon layer 14 having the prescribed pattern is formed.
(4) Finally, the MOS transistor 20 is formed on the SOI substrate 100 as shown in FIG. 1. The MOS transistor 20 is formed by commonly used processes of forming the MOS transistor. One example of such processes is described below.

First, the gate insulating layer 22 is formed on the strained silicon layer 14. The gate insulating layer 22 is formed by, for example, a thermal oxidation method. Then, impurity ion to control a thresh-hold voltage is injected into a channel region through the gate insulating layer 22, and then the channel region is formed.

Second, a polycrystalline silicon layer serving as the gate electrode 24 is formed on the gate insulating layer 22 by a low pressure chemical vapor deposition method. Then, the polycrystalline silicon layer is patterned by anisotropic etch, such as reactive ion etching (RIE), and the gate electrode 24 is formed.

Third, impurity ion having a predetermined conductivity type is injected selectively using the gate electrode 24 as a mask. Then the extension region 30, which is formed of a low level impurity layer, is formed in a self-aligning manner. If necessary, an annealing treatment can be carried out in this process.

Fourth, a insulating layer (not shown in the figures), such as a silicon oxide film or a silicon nitride film, is formed overall by the CVD method. Then, the sidewall insulating layer 26 is formed on the sides of the gate insulating layer 22 and the gate electrode 24 by etching the insulating layer back. Then, the source-drain region 28 is formed, in the self-aligning manner, by injecting the impurity ion using the sidewall insulating layer 26 as a mask. In above-described manner, the MOS transistor 20 is finally formed and the semiconductor device according to the first exemplary embodiment is made.

According to the method of manufacturing a semiconductor device of the first exemplary embodiment of the present invention, the strain silicon layer is formed by promoting the lattice relaxation in the single-crystal silicon layer after the strain promoting semiconductor layer is formed on the single-crystal silicon layer. The lattice relaxation of the single-crystal silicon layer is carried out to match with the lattice constant of the strain promoting semiconductor layer formed above. As a result, the strain silicon layer is obtained. In the related art technology described above, the lattice relaxation is driven after the silicon layer is formed on the thick silicon germanium mixed crystal layer (strain promoting semiconductor layer), and then the strain silicon layer is obtained. However, with an aspect of the present invention, it is not necessary to form such thick strain promoting semiconductor layer, and the SOI substrate including the strain silicon layer can be obtained by more simple methods. Further, since a thin strain silicon layer is formed according to as aspect of the present invention, typical advantages of the SOI substrate, such as lower parasitic capacitance can be obtained. It results in the semiconductor device having a fine attribute. Therefore, the field-effect transistor which has expected element's characteristics is realized even when it is further miniaturized.

Further, in the first exemplary embodiment of the present invention, the strained silicon layer 14 is only formed in the region where the semiconductor element (MOS transistor 20) is formed by using the single-crystal silicon layer 14b having the prescribed pattern. In this manner, the strained silicon layer 14 is formed in a limited area, so that the uniformly strained silicon layer 14 can be easily formed compared to a case which the strained layer is formed on an entire surface of the substrate. Consequently, the semiconductor device having fine element characteristics can be manufactured.

2.2 Second Exemplary Embodiment

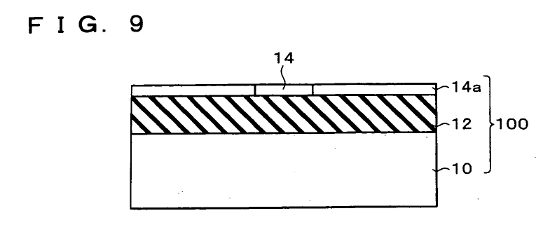

A method of manufacturing a semiconductor device according to the second exemplary embodiment of the present invention is described with reference to FIG. 7 through 9. In the method of manufacturing a semiconductor device according to the second exemplary embodiment, a process of forming the strained silicon layer having the prescribed pattern is different from that of the first exemplary embodiment. Detailed explanations for the processes similar to those in the first exemplary embodiment are omitted.
(1) First, the SOI substrate 100, which has the insulating layer 12 and the semiconductor layer formed on the support substrate 10, is provided in the same way as the first exemplary embodiment. In this exemplary embodiment, the single-crystal silicon layer 14a is employed as the semiconductor layer. Then, a mask layer M2, which has an opening in a predetermined region of the single-crystal silicon layer 14a, is formed as shown in FIG. 7. As the mask layer M2, a mask which has an opening placed over the active region of the semiconductor element (the channel region of the MOS transistor 20) can be formed. The mask layer M2 is formed by commonly used etching or lithography techniques and it can be formed of, for example, the oxide silicon layer.
(2) Second, as shown in FIG. 8, the strain promoting semiconductor layer 16 is formed where the single-crystal silicon layer 14a is not covered with the mask layer M2 by the epitaxial growth method. The strain promoting semiconductor layer 16 is formed in the same way as the first exemplary embodiment.
(3) Third, the strained silicon layer 14 is formed in the same way as a second process (2) of the first exemplary embodiment. Then the strained silicon layer 14 is obtained as shown in FIG. 9 after the heating treatment. The heat treatment is given in the same way as that of the first exemplary embodiment.
(4) Finally, the MOS transistor 20 is formed in the same way as a third process (3) of the first exemplary embodiment. In this process, the gate insulating layer and the gate electrode are formed on the strained silicon layer 14, and the MOS transistor 20, whose channel region is made of the strained silicon layer 14, is formed.

According to the method of manufacturing a semiconductor device of the second exemplary embodiment of the present invention, the fine strained silicon layer, which has the same advantages as those of the first exemplary embodiment, is formed by simple methods. Consequently, the semiconductor device having fine element characteristics can be manufactured.

Also, according to the method of the second exemplary embodiment, the mask layer M2 is formed on the single-crystal silicon layer 14a. The strained silicon layer 14 is formed on a predetermined limited area by forming the strain promoting semiconductor layer 16 only where the single-crystal silicon layer is not covered with the mask layer M2. Therefore, when one semiconductor element out of a plurality of semiconductor elements, which are equipped on the same substrate, is needed to be enhanced, the one semiconductor can be formed separately from the other semiconductor elements by applying the methods of the present invention. Further, when the strained silicon layer 14 is formed in a limited area, more uniformly strained silicon layer can be obtained compared to a case which the strained layer is formed on the entire surface of the substrate. Consequently, the semiconductor device having an enhanced quality can be manufactured.

The present invention is not limited to the above-described exemplary embodiments. For example, the silicon germanium layer is used for the strain promoting semiconductor layer in the above-described exemplary embodiments. A mixed crystal of Si and other elements, such as SiC and SiN can be used instead of the silicon germanium layer. Other mixed crystals which are made of materials having different lattice constants, such as an II-VI compound semiconductor, for example ZnSe, or an III-V compound semiconductor, such as GaAs and InP, can be also used for the strain promoting semiconductor layer.

In the above-described exemplary embodiments, a case where the MOS transistor is formed is explained, though the present invention may be also applied to any semiconductor devices which have the strained silicon layers as those channel semiconductor layers.

In the method of manufacturing a semiconductor device of the second exemplary embodiment, the case that the strained silicon layer 14 is only formed where an active region of the semiconductor element (the channel region of the MOS transistor 20) is formed, is explained. Though, the strained silicon layer 14 can be formed on overall the substrate in the same way as the first exemplary embodiment.

1. A method of manufacturing a semiconductor device, comprising:
providing a substrate including an insulating layer and a single-crystal silicon layer that has a prescribed pattern and is formed at the insulating layer;
forming a strain promoting semiconductor layer, whose lattice constant is different from that of the single-crystal silicon layer, at the single-crystal silicon layer;
forming a strained silicon layer by matching the single-crystal silicon layer to the strain promoting semiconductor layer; and
removing the strain promoting semiconductor layer.

2. The method of manufacturing a semiconductor device according to claim 1, further comprising:
patterning the single-crystal silicon layer at an entire surface of the insulating layer when the substrate is provided.

3. A method of manufacturing a semiconductor device, comprising:
providing a substrate including an insulating layer and a single-crystal silicon layer formed at the insulating layer;
forming a strain promoting semiconductor layer whose lattice constant is different from that of the single-crystal silicon layer at a prescribed region of the single-crystal silicon layer;
forming a strained silicon layer by matching the single-crystal silicon layer to the strain promoting semiconductor layer; and
removing the strain promoting semiconductor layer.

4. The method of manufacturing a semiconductor device according to claim 3, the strain promoting semiconductor layer being formed after a mask layer having a prescribed pattern is formed at the single-crystal silicon layer.

5. The method of manufacturing a semiconductor device according to claim 1, the strained silicon layer being formed by giving a heat treatment.

6. The method of manufacturing a semiconductor device according to claim 1, the single-crystal silicon layer having a smaller thickness than a thickness in which a defect-free single-crystal silicon layer is formed at the strain promoting semiconductor layer.

7. The method of manufacturing a semiconductor device according to claim 1, a layer that contains germanium being formed as the strain promoting semiconductor layer.

8. The method of manufacturing a semiconductor device according to claim 1, the strain promoting semiconductor layer being removed by a wet etching using a boiled nitric acid.

9. The method of manufacturing a semiconductor device according to claim 1, the strain promoting semiconductor layer being formed by any one of a metal organic chemical vapor deposition method, a molecular beam epitaxy method and an ultra high vacuum chemical vapor deposition method.

10. The method of manufacturing a semiconductor device according to claim 1, the heat treatment being carried out through a warm-up process, a fixed temperature process and a cool down process.

11. A semiconductor device, comprising:
a field-effect transistor having the strained silicon layer, obtained by the method of manufacturing the strained silicon layer according to claim 1, as an active region.
